(19) United States
(12) Patent Application Publication
(10) Pub. No.: US 2008/0164499 A1
(43) Pub. Date: Jul. 10, 2008

(54) METHOD OF MANUFACTURING CMOS IMAGE SENSOR

(76) Inventors: Ki-Sik Im, Daegu (KR); Woo Seok Hyun, Incheon (KR)

Correspondence Address: SHERR & NOURSE, PLLC, 620 HERNDON PARKWAY, SUITE 200, HERNDON, VA, 20170, US

(21) Appl. No.: 11/963,488

(22) Filed: Dec. 21, 2007

(30) Foreign Application Priority Data
Dec. 29, 2006 (KR) 10-2006-0137288

(51) Int. Cl. H01L 31/0232; H01L 21/308

(52) U.S. Cl. 257/292; 438/70; 257/E31.128; 257/E21.219; 257/E21.231

(57) ABSTRACT

A method of a CMOS image sensor is disclosed. A method of manufacturing a CMOS image sensor includes forming an epi layer formed over a semiconductor substrate including a pixel region and a peripheral region. At least one oxide film may be formed over the epi layer, including the peripheral region and an upper pad formed therein. A nitride film may be formed over the oxide film. A primary array etching process may be performed with respect to the nitride film using a first photoresist pattern for opening a main pixel region in the pixel region. A secondary array etching process may be performed with respect to the nitride film and the oxide film using a second photoresist pattern for opening the upper pad. The oxide film of the pixel region may be obliquely removed to a predetermined depth. A plurality of color filters and a plurality of micro lenses may be formed over the pixel region after the secondary array etching process.

The present application claims priority under 35 U.S.C. 119 to Korean Patent Application No. 10-2006-0137288, filed on Dec. 29, 2006, which is hereby incorporated by reference in its entirety.

### BACKGROUND

An image sensor converts an optical image into an electric signal. Image sensor may be classified as complementary metal oxide silicon (CMOS) image sensors or charge coupled device (CCD) image sensors. The CCD image sensor has relatively higher photosensitivity and lower noise than CMOS image sensors. However, CCD image sensors are more difficult to miniaturize, and integrate with other devices. Power consumption of the CCD image sensor is also higher. On the other hand, CMOS image sensors are prepared using a more simplified process than CCD image sensors. CMOS image sensors are easier to miniaturize, and integrate with other devices. Power consumption of the CCD image sensor is also higher.

With advances in technologies for preparing semiconductor devices, technology for preparing the CMOS image sensors, and consequently the characteristics of the CMOS image sensors, have been greatly improved. Accordingly, much research has been recently carried out on the CMOS image sensor.

A pixel of the CMOS image sensor includes photodiodes for receiving light and CMOS devices for controlling image signals from the photodiodes. The photodiodes generate electron-hole pairs, depending on the wavelength and intensity of red light, green light, and blue light incident through color filters. The photodiodes change an output signal, based on the amount of electrons generated. The aggregate of output signals from the photodiodes makes possible the detection of an image.

FIG. 1 is a view illustrating a problem which occurs in a related method of manufacturing a CMOS image sensor. As shown in FIG. 1, a CMOS image sensor includes a pixel region, and a peripheral circuit region. The pixel region includes photoelectric conversion portions such as photodiodes. The peripheral circuit region includes a plurality of circuits and pads for detecting signals output from the pixel region. The peripheral circuit region surrounds the pixel region.

A related method of manufacturing the CMOS image sensor will now be described. An epi layer (not shown) is formed over a semiconductor substrate including the photodiodes. A plurality of passivation layers 2 and 3 are formed over the epi layer. Subsequently, the upper passivation layer 3 is etched to form a color filter array (CFA) 4 including a plurality of color filters. Thereafter, a plurality of micro lenses 5 are formed over the CFA 4.

The upper passivation layer 3 is etched through an array etching technology for forming the CFA 4 to reduce the thickness thereof such that a large amount of light reaches the photodiodes for receiving the light. Accordingly, the photosensitivity of the photodiodes can be improved.

However, when the related array etching technology is used, the upper passivation layer 3 may be deeply etched. Thus, a step difference occurs in the pixel region. Due to the step difference, deformation may occur in subsequent processes including a process of forming the CFA 4 and a process of forming micro lenses 5. That is, the CFA 4 and the micro lens 5 are deformed near the step, as denoted by a reference numeral “A”. Therefore, the upper passivation layer 3 should be etched more shallowly, and less deeply.

However, if the upper passivation layer 3 is etched more shallowly, the distance between the micro lenses 5 and the photodiodes is increased due to the thickness of the upper passivation layer 3 and light transmission efficiency may deteriorate.

### SUMMARY

Embodiments relate to a method of manufacturing a CMOS image sensor, which is capable of preventing a color filter array and micro lenses from being deformed due to a step difference in an upper passivation layer formed by an array etching process. Embodiments relate to a method of manufacturing a CMOS image sensor which includes forming an epi layer formed over a semiconductor substrate including a pixel region and a peripheral region. At least one oxide film may be formed over the epi layer, including the peripheral region and an upper pad formed therein. A nitride film may be formed over the oxide film. A primary array etching process may be performed with respect to the nitride film using a first photoresist pattern for opening a main pixel region in the pixel region. A secondary array etching process may be performed with respect to the nitride film and the oxide film using a second photoresist pattern for opening the upper pad. The oxide film of the pixel region may be obliquely removed to a predetermined depth. A plurality of color filters and a plurality of micro lenses may be formed over the pixel region after the secondary array etching process.

In embodiments, the method may further include forming a contact hole in the upper pad. The method may further include removing the first photoresist pattern after the primary array etching process. In embodiments, the nitride film may be etched through the primary array etching process such that the oxide film is partially exposed. In embodiments, the forming of the oxide film may include forming a first oxide film over the epi layer; forming the upper pad over the first oxide film in the peripheral region; and forming a second oxide film to cover the upper pad.

Embodiments relate to a method of manufacturing a CMOS image sensor which includes forming a lower passivation layer over an epi layer of a semiconductor substrate including a pixel region and a peripheral region, An upper pad may be formed over the lower passivation layer of the peripheral region. An upper passivation layer may be formed so as to cover the upper pad. A primary array etching process may be performed with respect to the upper passivation layer such that the lower passivation layer is partially exposed using a first photoresist pattern for opening a main pixel region of the pixel region. An undoped silicate glass (USG) film may be formed having a predetermined slope over the entire surface of the substrate including the upper passivation layer remaining after the primary array etching process. A nitride film may be formed having a predetermined slope over the USG film. A secondary array etching process may be performed with respect to the nitride film and the upper and lower passivation layers using a second photoresist pattern for opening the upper pad such that the upper pad is exposed. A plurality of color filters and a plurality of micro lenses may be formed in the pixel region after the secondary array etching process.

In embodiments, a photoresist may be coated over the nitride film and may be cured such that the nitride film is gently sloped. In embodiments, the forming of the USG film may include depositing USG using a high density plasma chemical vapor deposition (HDPCVD) process.

### DRAWINGS

FIG. 1 is a view illustrating a problem which occurs in a related method of manufacturing a CMOS image sensor.

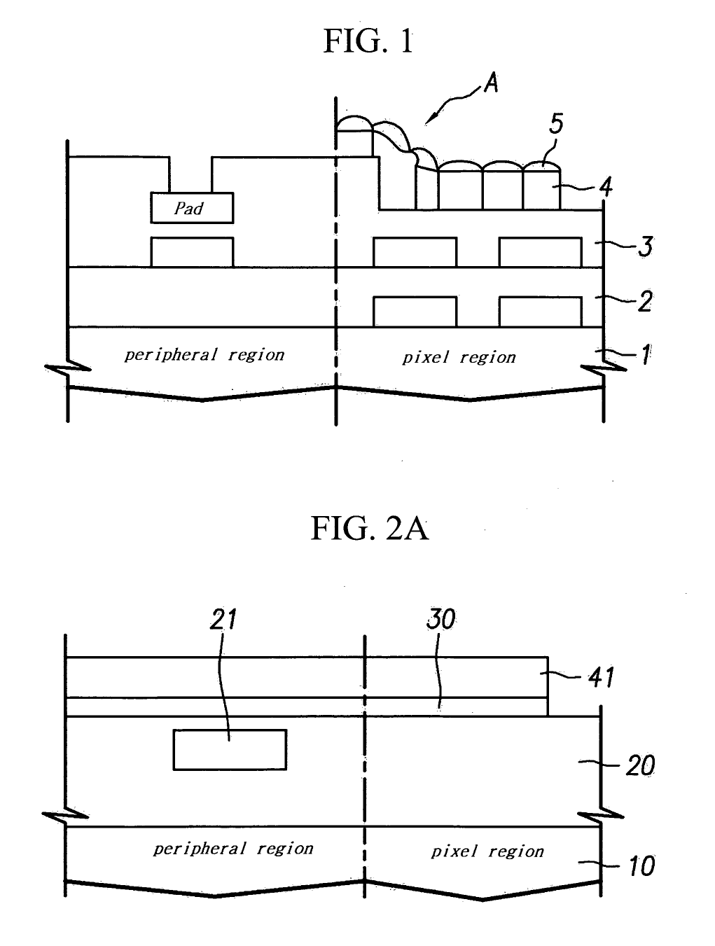

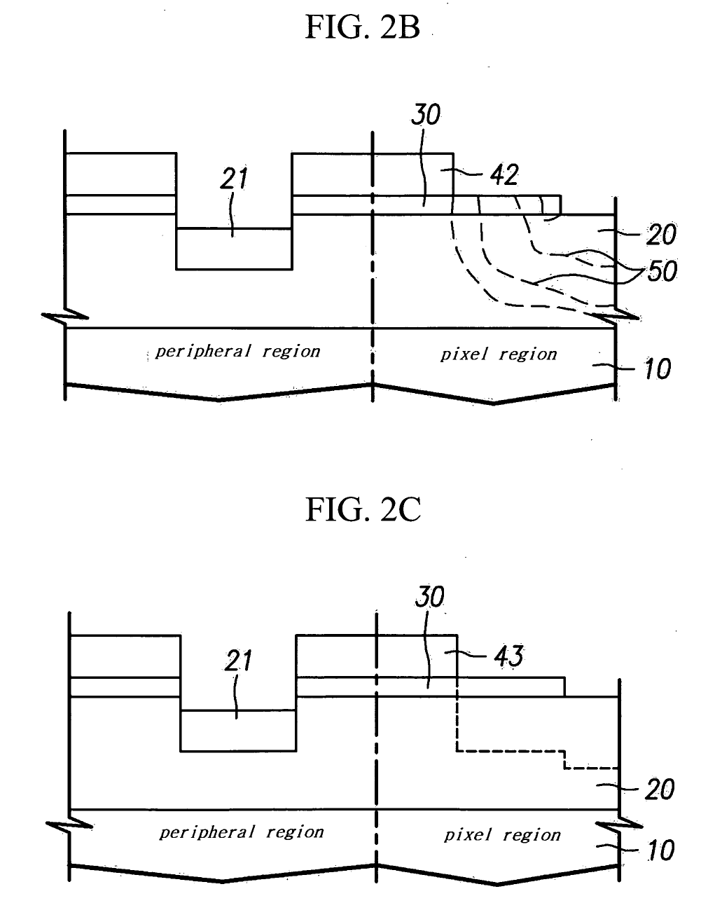

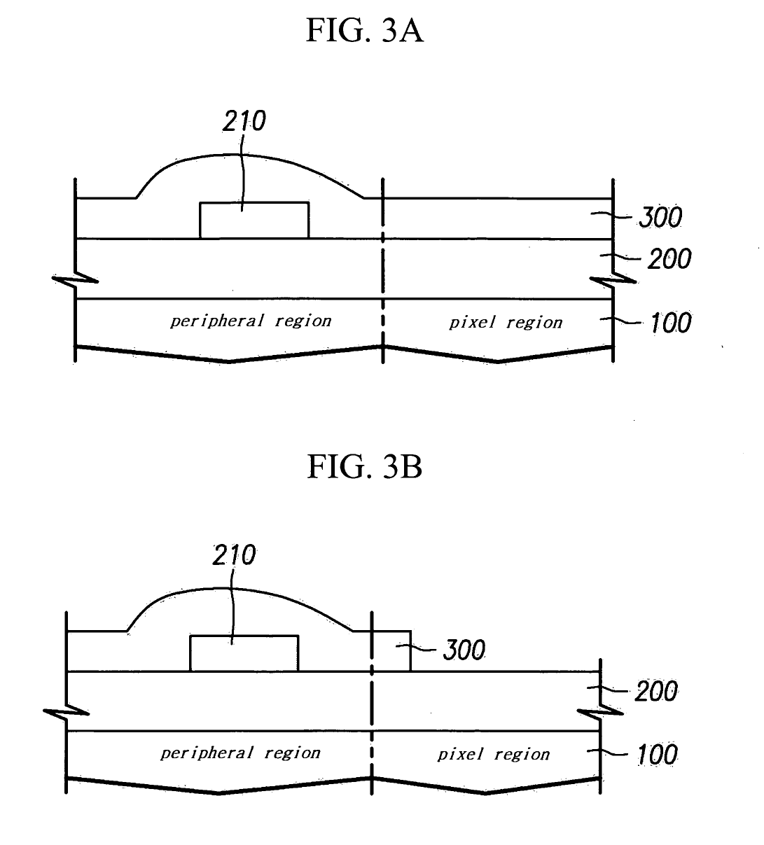

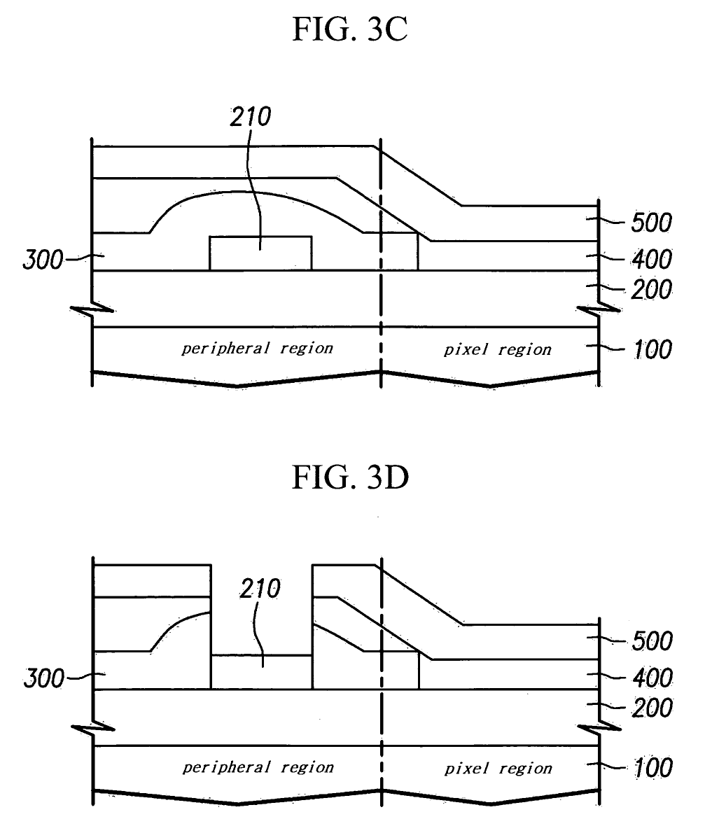

Example FIGS. 2A to 2C are cross-sectional views illustrating a method of manufacturing a CMOS image sensor according to embodiments.

Example FIGS. 3A to 3D are cross-sectional views illustrating a method of manufacturing a CMOS image sensor according to embodiments.

### DESCRIPTION

Example FIGS. 2A to 2C are cross-sectional views illustrating a method of manufacturing a CMOS image sensor according to embodiments. As shown in example FIG. 2A, the CMOS image sensor according to embodiments includes an epi layer 10 formed over a lower surface thereof. In other words, the epi layer 10 is formed over a semiconductor substrate. The epi layer 10 includes a pixel region, in which photoelectric conversion portions such as photodiodes are formed. The epi layer also includes a peripheral region with a plurality of circuits and pads for detecting signals output from the pixel region. In other words, layers formed over the semiconductor substrate may be defined by the pixel region and the peripheral region. Hereinafter, it is assumed that a plurality of layers according to embodiments are formed over the semiconductor substrate including the pixel region and the peripheral region.

A passivation layer 20 is formed over the epi layer 10. The passivation layer 20 is, in embodiments, formed of an oxide film. When the passivation layer 20 is formed, a planarization process is performed to planarize the upper surface thereof. The passivation layer 20 is divided into a portion formed in the pixel region and a portion formed in the peripheral region. An upper pad 21 is included in the portion formed in the peripheral region.

A nitride film 30 is formed over the passivation layer 20. A first photoresist pattern 41 for opening a main pixel region in the pixel region is formed over the formed nitride film 30. The nitride film 30 is, for example, formed of Si₃N₄.

After the nitride film 30 and the first photoresist pattern 41 are sequentially formed over the passivation layer 20, a primary array etching process is performed with respect to the pixel region. That is, the nitride film 30 is subjected to a primary array etching process using the first photoresist pattern 41 formed in the pixel region. Accordingly, the passivation layer 20 formed in the pixel region is partially exposed through the primary array etching process.

After the passivation layer 20 is exposed by the primary array etching process, as shown in example FIG. 2B, a secondary array etching process is performed on the peripheral region and the pixel region. That is, the secondary array etching process is performed in order to open the upper pad 21 of the peripheral region and form a space for forming color filters and micro lenses in the pixel region.

The secondary array etching process is performed after the first photoresist pattern 41 used in the primary array etching process is removed. The secondary array etching process is performed using a second photoresist pattern 42 for opening the region of the upper pad 21 of the peripheral region. The nitride film 30 and the passivation layer 20 are etched through the secondary array etching process such that the upper pad 21 of the peripheral region is exposed.

Simultaneously, an isotropic etching process is performed with respect to the passivation layer 20 of the pixel region along dotted lines 50 shown in example FIG. 2B. A space for forming the color filters and the micro lenses are formed at the same depth as the upper pad 21 through the isotropic etching process such that the space is gently sloped. Additionally, a photoresist may be coated over a portion of the pixel region having a profile denoted by the dotted lines 50 and may be cured, such that the space is more gently sloped.

As shown in example FIG. 2C, after the first photoresist pattern 41 is removed, the nitride film 30 and the passivation layer 20 are etched using a third photoresist pattern 43 for opening the region of the upper pad 21. The upper pad 21 of the peripheral region is exposed. At the same time, an anisotropic reactive ion etching (RIE) process is performed on the passivation layer 20 of the pixel region to form a profile of the passivation layer 20 having the same shape as a step difference of the nitride film 30 as denoted by the dotted lines 50. Accordingly, it is possible to prevent deformation from occurring in subsequent processes including a process of forming a color filter array and a process of forming the micro lenses, due to the step difference of the pixel region. Alternatively, after the profile of the passivation layer 20 is formed as denoted by a dotted line of example FIG. 2C, a photoresist may be coated over the step difference portion denoted by the dotted line and then cured so as to have a gentler slope.

A method of manufacturing the CMOS image sensor according to embodiments will be described with reference to example FIGS. 3A to 3D. As shown in example FIG. 3A, the CMOS image sensor according to embodiments includes an epi layer 100 formed over a lower surface of the substrate. The epi layer 100 is formed over the entire surface of a semiconductor substrate including a pixel region and a peripheral region.

The epi layer 100 includes a pixel region, in which photoelectric conversion portions such as photodiodes are formed, and a peripheral region including a plurality of circuits and pads for detecting signals output from the pixel region. A plurality of passivation layers 200 and 300 are formed over the epi layer 100. The passivation layers 200 and 300 are, in embodiments, formed of oxide films. In the plurality of passivation layers 200 and 300 formed over the epi layer 100, the upper passivation layer 300 is formed over the flat lower passivation layer 200. When the lower passivation layer 200 is formed, a planarization process is performed on the upper surface of the lower passivation layer.

Subsequently, an upper pad 210 is formed over the upper surface of the lower passivation layer 200 in a region corresponding to the peripheral region. Then, the upper passivation layer 300 is formed so as to cover the upper pad 210. That is, the passivation layers 200 and 300 are divided into a portion formed in the pixel region and a portion formed in the peripheral region, and the upper pad 210 is included in the upper passivation layer 300 formed in the peripheral region.

The flat lower passivation layer 200 is formed of undoped silicate glass (USG) and the upper passivation layer 300 is formed of tetra ethyl ortho silicate (TEOS). As a result, after the upper passivation layer 300 is formed, a convex surface is formed in the peripheral region by coating the upper pad 210 with the upper passivation layer 300. After the upper passivation layer 300 is formed, a first photoresist pattern for opening the pixel region is formed over the upper passivation layer 300 and the upper passivation layer 300 is etched using the first photoresist pattern.

As shown in example FIG. 3B, the lower passivation layer 200 of the pixel region is partially exposed by etching the upper passivation layer 300. After the lower passivation layer 200 of the pixel region is exposed by the etching process, the first photoresist pattern is removed by an ashing process. USG is deposited over the entire surface of the substrate including the residual upper passivation layer 300, using a high density plasma chemical vapor deposition (HDPCVD) process.

Accordingly, as shown in example FIG. 3C, an USG film 400 having a gentle slope is formed. Thereafter, the USG film 400 is planarized using a chemical-mechanical polishing (CMP) process. Alternatively, the USG film 400 may be etched using NH₃ based or CₓF_{y} based plasma such that the USG film 400 is formed with a thickness of approximately 2000 Å to 3000 Å while having a gentle slope.

After the USG film 400 is formed, as shown in example FIG. 3C, for example, a nitride film 500 formed of Si₃N₄ is formed over the USG film 100 having the gentle slope. The nitride film 500 has a slope substantially similar to that of the USG film 400.

After the nitride film 500 is formed, as shown in example FIG. 3D, a photoresist pattern for forming a contact hole connected to the upper pad 210 of the peripheral region is formed over the nitride film 500. A dry etching process for forming the contact hole is performed using the photoresist pattern. Thereafter, a plurality of color filters and micro lenses are sequentially formed over the nitride film 500 of the pixel region. Alternatively, before the nitride film 500 is formed and the plurality of color filters and micro lenses are sequentially formed, a photoresist may be coated over the nitride film 500 of the pixel region and may be cured so as to have a gentler slope.

Accordingly, when the array etching process is performed according to embodiments, a space for forming the plurality of color filters and micro lenses can be formed deeper and thus a step difference is prevented from occurring. Therefore, it is possible to prevent deformation from occurring in the subsequent processes including the process of forming the color filter array and the process of forming the micro lenses, due to the step difference of the pixel region.

As described above, according to embodiments, since a space for forming a plurality of color filters or micro lenses can be formed deeper when an array etching process is performed, a distance between the micro lenses and photodiodes is reduced and thus light coupling efficiency can be improved.

Since a step difference of a pixel region which occurs when an array etching process is performed can be prevented, it is possible to efficiently prevent deformation from occurring in subsequent processes including a process of forming a color filter array and a process of forming micro lenses, due to the step difference of the pixel region.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an epi layer formed over a semiconductor substrate including a pixel region and a peripheral region;
forming at least one oxide film over the epi layer, the oxide film formed over the epi layer of the peripheral region including an upper pad formed therein;
forming a nitride film over the oxide film;
performing a primary array etching process on the nitride film using a first photoresist pattern for opening a main pixel region of the pixel region;
performing a secondary array etching process on the nitride film and the oxide film using a second photoresist pattern for opening the upper pad and obliquely removing the oxide film of the pixel region to a predetermined depth; and
forming a plurality of color filters and a plurality of micro lenses over the pixel region.

2. The method of claim 1, comprising forming a contact hole in the upper pad.

3. The method of claim 1, comprising removing the first photoresist pattern after the primary array etching process.

4. The method of claim 1, wherein the nitride film is etched through the primary array etching process such that the oxide film is partially exposed.

5. The method of claim 1, wherein after the oxide is obliquely etched to the predetermined depth, a photoresist is coated over the oxide film in the pixel region and is cured so as to have a gentle slope.

6. The method of claim 1, wherein an isotropic etching process is performed by the secondary array etching process.

7. The method of claim 1, wherein an anisotropic reactive ion etching process is performed by the secondary array etching process.

8. The method of claim 1, wherein the forming of the oxide film comprises:
forming a first oxide film over the epi layer;
forming the upper pad over the first oxide film in the peripheral region; and
forming a second oxide film to cover the upper pad.

9. The method of claim 7, comprising planarizing the first oxide film before forming the second oxide film.

10. The method of claim 1, wherein the nitride film is formed of Si₃N₄.

11. A method comprising:
forming a lower passivation layer over an epi layer of a semiconductor substrate including a pixel region and a peripheral region;
forming an upper pad over the lower passivation layer of the peripheral region;
forming an upper passivation layer so as to cover the upper pad;
performing a primary array etching process on the upper passivation layer such that the lower passivation layer is partially exposed using a first photoresist pattern for opening a main pixel region of the pixel region;
forming an undoped silicate glass film having a predetermined slope over the entire surface of the substrate including the upper passivation layer remaining after the primary array etching process;
forming a nitride film having a predetermined slope over the undoped silicate glass film;
performing a secondary array etching process with respect to the nitride film and the upper and lower passivation layers using a second photoresist pattern for opening the upper pad such that the upper pad is exposed; and
forming a plurality of color filters and a plurality of micro lenses in the pixel region after the secondary array etching process.

12. The method of claim 11, wherein a photoresist is coated over the nitride film and is cured such that the nitride film is gently sloped.

13. The method of claim 11, wherein the USG film is planarized using a chemical-mechanical polishing process.

14. The method of claim 11, wherein the forming of the undoped silicate glass film comprises depositing undoped silicate glass using a high density plasma chemical vapor deposition process.

15. The method of claim 11, wherein the undoped silicate glass film is formed with a thickness of approximately 2000 Å to 3000 Å.

16. The method of claim 11, comprising etching the undoped silicate glass film using NH₃-based plasma such that the undoped silicate glass film is more gently sloped.

17. The method of claim 11, comprising etching the undoped silicate glass film using CₓF_{y}-based plasma such that the undoped silicate glass film is more gently sloped.

18. The method of claim 11, wherein the upper passivation layer is formed of tetra ethyl ortho silicate.

19. An apparatus comprising:
an epi layer formed over a semiconductor substrate including a pixel region and a peripheral region;
at least one oxide film formed over the epi layer, the oxide film formed over the epi layer of the peripheral region including an upper pad formed therein;
a nitride film formed over the oxide film;
an opening etched into the nitride layer over a main pixel region of the pixel region;
an opening etched into the nitride film and the oxide film over the upper pad and the oxide film of the pixel region;
a plurality of color filters and a plurality of micro lenses formed over the pixel region; and
a cured photoresist coated over the oxide film in the pixel region, the photoresist having a gentle slope.

20. The apparatus of claim 19, wherein the oxide film comprises:
a first oxide film formed over the epi layer, wherein said upper pad is formed over the first oxide film in the peripheral region; and
a second oxide film covering the upper pad.
